(19) United States
(12) Patent Application Publication
(10) Pub. No.: US 2014/0138730 A1
(43) Pub. Date: May 22, 2014

(54) Method of Producing a Plurality of Optoelectronic Semiconductor Chips

(71) Applicants: Martin Reufer, Reken (DE); Markus Maute, Alteglofsheim (DE); Tony Albrecht, Bad Abbach (DE)

(72) Inventors: Martin Reufer, Reken (DE); Markus Maute, Alteglofsheim (DE); Tony Albrecht, Bad Abbach (DE)

(73) Assignee: OSRAM OPTO SEMICONDUCTORS GMBH, Regensburg (DE)

(21) Appl. No.: 14/126,033

(22) PCT Filed: Jun. 1, 2012
(86) PCT No.: PCT/EP2012/060393

§ 371 Date: Feb. 4, 2014

(30) Foreign Application Priority Data
Jun. 17, 2011 (DE) 10 2011 104 515.9

(51) Int. Cl. H01L 33/24; H01L 33/00

(52) U.S. Cl. CPC H01L 33/24; H01L 33/0095
USPC 257/98; 438/29

(57) ABSTRACT

A method of producing a plurality of optoelectronic semiconductor chips is provided. At least one trench is incorporated into the semiconductor body by means of at least one structuring process. The trench breaks through the active zone in a vertical direction. At least one cleaning process is performed at least on exposed locations of the semiconductor body in the region of the trench. The cleaning process includes at least one plasma cleaning process, and the plasma cleaning process at least reduces a number and/or a spatial expansion of structuring residues at exposed locations of the semiconductor body at least in the region of the trench. At least one passivation layer is applied at least to exposed locations of the semiconductor body in the region of the trench.

This patent application is a national phase filing under section 371 of PCT/EP2012/060393, filed Jun. 1, 2012, which claims the priority of German patent application 10 2011 104 515.9, filed Jun. 17, 2011, each of which is incorporated herein by reference in its entirety.

### TECHNICAL FIELD

A method of producing a plurality of optoelectronic semiconductor chips, an optoelectronic semiconductor chip and an optoelectronic semiconductor device is disclosed.

### SUMMARY OF THE INVENTION

In embodiments of the invention, ageing-resistant optoelectronic semiconductor chips can be produced in a cost-effective manner.

In accordance with at least one embodiment of the method, in a first step a semiconductor body is initially provided which comprises a surface and at least one active zone suitable for the generation of radiation. For example, the semiconductor body is formed with an epitaxially grown semiconductor layer sequence. In this case, the semiconductor body can comprise the active zone. The active zone can be a layer or layer sequence which, when subjected to electrical contacting, emits electromagnetic radiation in a wavelength range within the ultraviolet to infrared spectral range of the electromagnetic radiation. During operation, the active zone emits electromagnetic radiation through the surface and can then escape from the semiconductor body through this surface. In other words, the electromagnetic radiation generated in the active zone within the semiconductor body is coupled out at least partially from the semiconductor body through this surface. The surface extends, e.g., perpendicularly with respect to a growth direction of the epitaxially produced semiconductor body.

In accordance with at least one embodiment of the method, in a next step at least one trench is incorporated into the semiconductor body by means of at least one structuring process over the surface of the semiconductor body, wherein in the region of the trench parts of the semiconductor body are removed. For example, removal is effected by the structuring process by means of physical and/or chemical removal of the material of the semiconductor body. That is to say, the trench is produced, e.g., by material removal. The trench is defined at least in locations in a lateral manner by the semiconductor body. In this regard, it is feasible for the at least one trench to have a base surface located opposite to an opening of the trench, as well as two lateral surfaces which are connected together by the base surface. The lateral surfaces and also the base surface can be formed by regions of the semiconductor body. In other words, the trench is a recess in the semiconductor body.

In accordance with at least one embodiment, the trench breaks through the active zone in a vertical direction. That is to say, that the at least one trench extends at least between the active zone and the surface of the semiconductor body and at these locations breaks through the intermediate material layers and the active zone. Then, the active zone is subdivided at certain locations where the at least one trench extends. If the semiconductor body comprises several active zones stacked one above the other, the at least one trench can break through at least one or even all of the active zones. In this regard, the phrase “vertical direction” refers to a direction in parallel with the growth direction of the semiconductor body.

In accordance with at least one embodiment, in a next step at least one cleaning process is performed at least on exposed locations of the semiconductor body in the region of the trench, wherein the cleaning process includes at least one plasma cleaning process. For example, the exposed locations of the semiconductor body include the lateral surfaces and/or the base surface of the trench. The cleaning process can then be performed at least on the lateral surfaces and/or the base surface of the trench. The plasma cleaning process reduces a number and/or a spatial expansion of structuring residues on the exposed locations of the semiconductor body at least in the region of the trench.

The structuring process is a manufacturing step by means of which, e.g., after the structuring process has been performed on the semiconductor body at exposed locations, e.g., in the region of the trench of the semiconductor body, structuring residues can be produced and can then remain adhered. Moreover, the structuring residues arising from the structuring process can be surrounded at least at certain locations by the material of the semiconductor body.

For example, the structuring residues are organic residues, e.g., a photoresist which was used during or in conjunction with the structuring process, and/or they are the material of the semiconductor body itself which has remained adhered to exposed locations of the semiconductor body in the trench and protrudes from this location. In other words, the material of the structuring residues can be different from the material of the semiconductor body. Moreover, such structuring residues can form irregularities on the lateral surfaces of the trench.

The plasma cleaning process can be an independent cleaning process or it can be an element of the cleaning process, in which by using and applying a plasma, e.g., a reactive plasma, on/to exposed locations of the semiconductor body at least in the region of the trench these locations can have the structuring residues removed therefrom and can thus be cleaned.

For example, a concentration of the structuring residues in the semiconductor material at least in the region of the trench after the plasma cleaning process has been performed is reduced at least by 80 wt. %, preferably by more than90 wt. %, in comparison with a concentration before the plasma cleaning process has been performed.

In accordance with at least one embodiment of the method, in a next step at least one passivation layer is applied at least to exposed locations of the semiconductor body in the region of the trench. It is feasible for the passivation layer to be applied additionally at least to locations on the further exposed outer surfaces, e.g., the surface of the semiconductor body. In this case, at least some locations of the passivation layer can be radiolucent to electromagnetic radiation which is emitted by the active zone. In this regard, the term “radiolucent” means that the passivation layer is at least up to 80%, preferably up to more than 90%, transparent to electromagnetic radiation which is emitted by the active zone. In particular, the passivation layer can be in direct contact with the semiconductor body, so that neither a gap nor a break is formed between the passivation layer and the semiconductor body. For example, the passivation layer prevents oxidation of the semiconductor material at the locations of the semiconductor body which are covered by it. Preferably, the passivation layer is electrically isolating. For example, the passivation layer is applied to the active zone at least in the region of the trench.

In accordance with at least one embodiment of the method, in a first step at least one semiconductor body is provided which comprises a surface and at least one active zone suitable for generating radiation. In a next step, at least one trench is incorporated into the semiconductor body by means of at least one structuring process performed over surface of the semiconductor body, wherein in the region of the trench parts of the semiconductor body are removed, and the trench breaks through the active zone in a vertical direction. In a next step, a cleaning process is performed at least on exposed locations of the semiconductor body in the region of the trench, wherein the cleaning process includes at least one plasma cleaning process, and the plasma cleaning process at least reduces a number and/or a spatial expansion of structuring residues at exposed locations of the semiconductor body at least in the region of the trench. In a next step, at least one passivation layer is applied at least to exposed locations of the semiconductor body in the region of the trench.

The method of producing a plurality of optoelectronic semiconductor chips, as described in this case, is based inter alia upon the knowledge that, e.g., adhesion and structural problems of the passivation layer can become apparent during or after application of at least one passivation layer in the region of a trench produced by means of a structuring process in a semiconductor body.

For example, there is the risk that even after a short time the passivation layer will become detached from the semiconductor body at certain locations or completely and/or will have irregularities and/or cracks at certain locations. Such problems can be attributed to structuring residues which are produced as the trench is incorporated into a semiconductor body of this type. For example, material residues and/or other residues, e.g., organic photoresists, can remain adhered to lateral surfaces of the trench and/or can protrude from the lateral surfaces.

If the passivation layer is applied two-dimensionally to the lateral surfaces, e.g., to such lateral surfaces of the trench, the adhesion and structural problems of the passivation layer can become apparent at these locations. For example, the passivation layer is then no longer completely electrically isolating in the region of the structuring residues. It is conceivable that electrical charges will be able to escape from an, e.g., doped region of the semiconductor body along the cracks and can form a leakage current with a further doped region of the semiconductor body along the lateral surfaces. During operation on the finished optoelectronic semiconductor chip, such leakage currents can lead to a fall-off in an operating voltage, resulting in the reduction of an optical output power of the optoelectronic semiconductor chip. In other words, a fall-off in the operating voltage, e.g., by virtue of such leakage currents, is an indication of a malfunction of the optoelectronic semiconductor chip.

By performing a cleaning process, which includes a plasma cleaning process, at least on exposed locations of the semiconductor body in the region of the trench, the method described in this case renders it possible in particular to reduce at least the number and/or spatial expansion of disruptive structuring residues which after application of the passivation layer lead to leakage currents. In other words, the method described in this case ensures in a cost-effective manner that after application of the passivation layer, e.g., onto the lateral surfaces, the passivation layer no longer forms, e.g., cracks and/or irregularities. The above-described leakage currents can thereby be avoided. Also, any air moisture contained in an ambient atmosphere of the semiconductor body is prevented from passing via, e.g., cracks in the passivation layer into the material of the semiconductor body and damaging, e.g., the subsequent optoelectronic semiconductor chip. An optoelectronic semiconductor chip which is produced in accordance with the method described in this case is therefore resistant to ageing.

In accordance with at least one embodiment, locations of the semiconductor body which are exposed after the plasma cleaning process has been performed are substantially free of structuring residues at least in the region of the trench. In this regard, the phrase “substantially free” means that a degree of surface coverage of exposed locations on the outer surfaces of the semiconductor body, in particular the exposed locations of the semiconductor body in the region of the trench, as caused by the structuring residues amounts at the most 1%, preferably at the most 0.5%.

In accordance with at least one embodiment, the plasma cleaning process includes the application of suitable gases, in particular Ar, Cl, F, N₂, N₂O and/or O₂, at least to the exposed locations of the semiconductor body in the region of the trench. It has been demonstrated that by using this type of plasma cleaning process the structuring residues can be removed in a particularly effective manner.

In accordance with at least one embodiment, the semiconductor body is based upon a III-nitride semiconductor material. In this regard, the term “III-nitride semiconductor material” means that the semiconductor body comprises or consists of a nitride semiconductor material, preferably AlₘGaₐIn₁₋ₙ₋ₘN, wherein 0≦m≦1, 0≦n≦1 and m+n≦1.

In accordance with at least one embodiment, the cleaning process includes at least one wet-chemical cleaning process.

In accordance with at least one embodiment, the wet-chemical cleaning process includes the application of a buffered, oxidized etchant (BOE) and/or the application of hydrofluoric acid to the exposed locations of the semiconductor body in the region of the trench.

For example, the wet-chemical cleaning process can be applied before or after the plasma cleaning process to exposed locations, e.g., in the region of the trench of the semiconductor body. In other words, the wet-chemical cleaning process can be combined with the plasma cleaning process depending upon the necessary requirements. This results in the most variable and individually useable cleaning process.

In accordance with at least one embodiment, the wet-chemical cleaning process is initially applied to the exposed locations of the semiconductor body in the region of the trench and subsequently the plasma cleaning process is performed on these locations. In other words, the wet-chemical cleaning process serves to provide a, e.g., rough pre-cleaning of these locations to partially remove coarse-grained residues. However, the wet-chemical cleaning process described in this case does not facilitate a reduction in the structuring residues, particularly not in comparison with the plasma cleaning process described in this case. Cleaning, i.e., removing structuring residues from the exposed locations of the semiconductor body at least in the region of the trench, only takes place by reason of the plasma cleaning process. It has been found that by incorporating the wet-chemical process upstream of the plasma cleaning process the number and/or the spatial expansion of the structuring residues can be reduced in a particularly effective manner. In other words, the rough cleaning effects of the wet-chemical cleaning process can be combined with the fine cleaning effects of the plasma cleaning process to produce the most effective cleaning process possible.

In accordance with at least one embodiment, the passivation layer is formed with, or contains, at least one of the materials SiO₂, SiN, TiO₂, Al₂O₃ and/or Si.

In accordance with at least one embodiment, the semiconductor body is separated into individual optoelectronic semiconductor chips in the region of the trench. For example, the semiconductor body is separated by means of high-energy laser light. It is also possible for the semiconductor body to be separated by scoring and subsequent breaking or cutting.

An optoelectronic semiconductor chip is also provided. For example, the semiconductor chip can be produced by a method as described in conjunction with one or several of the aforementioned embodiments. This means that the features listed for the method described in this case are also disclosed for the optoelectronic semiconductor chip described in this case, and vice versa.

In accordance with at least one embodiment, the optoelectronic semiconductor chip includes a semiconductor body which comprises a surface and at least one active zone suitable for generating radiation.

In accordance with at least one embodiment, the optoelectronic semiconductor chip includes at least one passivation layer which is applied at least to exposed locations of the semiconductor body at least in the region of lateral flanks of the semiconductor body.

The lateral flanks of the semiconductor body define the semiconductor body in a lateral direction. The phrase “lateral direction” is a direction, e.g., perpendicular to the growth direction of the semiconductor body. The passivation layer covers at least the lateral flanks partially or completely, in particular in the region of the active zone, and thus prevents, e.g., oxidation of the material of the active zone on the lateral flank.

In accordance with at least one embodiment, the semiconductor body is substantially free of structuring residues at least on the lateral flanks. In particular, the passivation layer can also be substantially free of the structuring residues. In this regard, the phrase “substantially free” means that a respective degree of surface coverage of the outer surface of the semiconductor body, in particular the lateral flanks, and the outer surface of the passivation layer, as caused by the structuring residues, amounts at the most 1%, preferably at the most 0.5%.

In accordance with at least one embodiment, the passivation layer is free of any interruptions at the applied locations. This means that at these locations the passivation layer does not have a crack and/or a gap. In particular, at the applied locations the passivation layer can be in direct contact with the lateral flanks of the semiconductor body.

An optoelectronic semiconductor device is also provided. The optoelectronic semiconductor device comprises a plurality of the optoelectronic semiconductor chips described in this case. This means that the features listed for the optoelectronic semiconductor chip described in this case are also disclosed for the optoelectronic semiconductor device described in this case, and vice versa.

For example, the optoelectronic semiconductor device comprises a common carrier, on which the optoelectronic semiconductor chips are applied and contacted in an electrically conductive manner. For example, the optoelectronic semiconductor chips are electrically interconnected by means of the carrier.

### BRIEF DESCRIPTION OF THE DRAWINGS

The method described in this case, the optoelectronic semiconductor chip and the optoelectronic semiconductor device will be explained in greater detail hereinafter with reference to exemplified embodiments and the associated Figures, in which:

FIGS. 1A, 1B, 1C and 1D show schematic lateral views of individual method steps for producing a plurality of optoelectronic semiconductor chips described in this case;

FIG. 1E shows a schematic lateral view of an optoelectronic semiconductor chip, in which for the production thereof the plasma cleaning process described in this case is omitted;

FIGS. 2A, 2B and 2C show microscopic images during individual manufacturing steps of the method described in this case;

FIG. 3A shows a schematic plan view of an exemplified embodiment of an optoelectronic semiconductor device described in this case; and

FIG. 3B shows a plotted graph of an operating voltage of individual optoelectronic semiconductor chips—described in this case—of the optoelectronic semiconductor device described in FIG. 3A.

In the exemplified embodiments and Figures, identical components or components which act in an identical manner are provided with the same reference numerals. The illustrated elements are not to be viewed as being to scale. On the contrary, individual elements can be illustrated in greatly exaggerated fashion for improved understanding.

### DETAILED DESCRIPTION OF ILLUSTRATIVE EMBODIMENTS

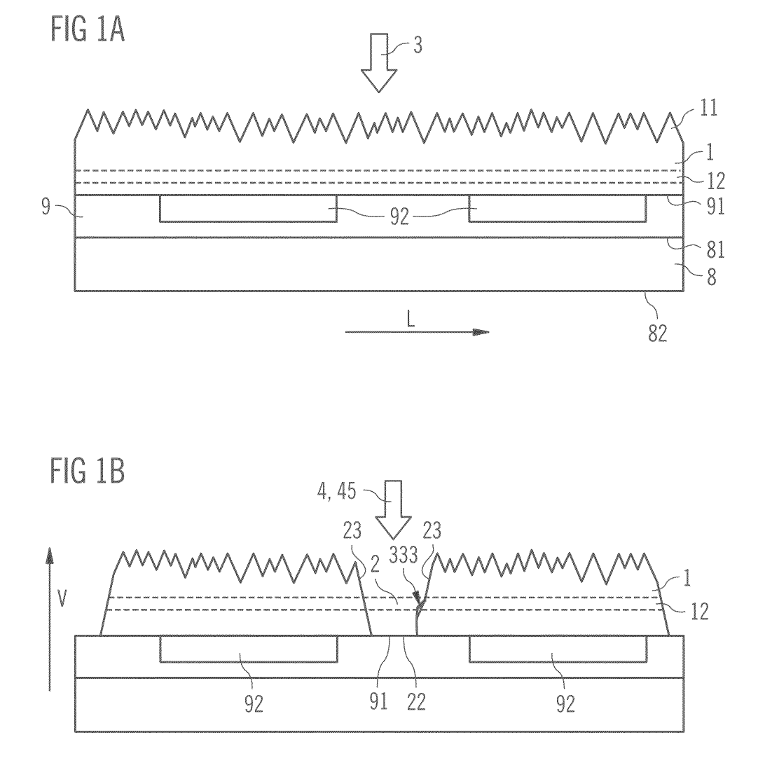

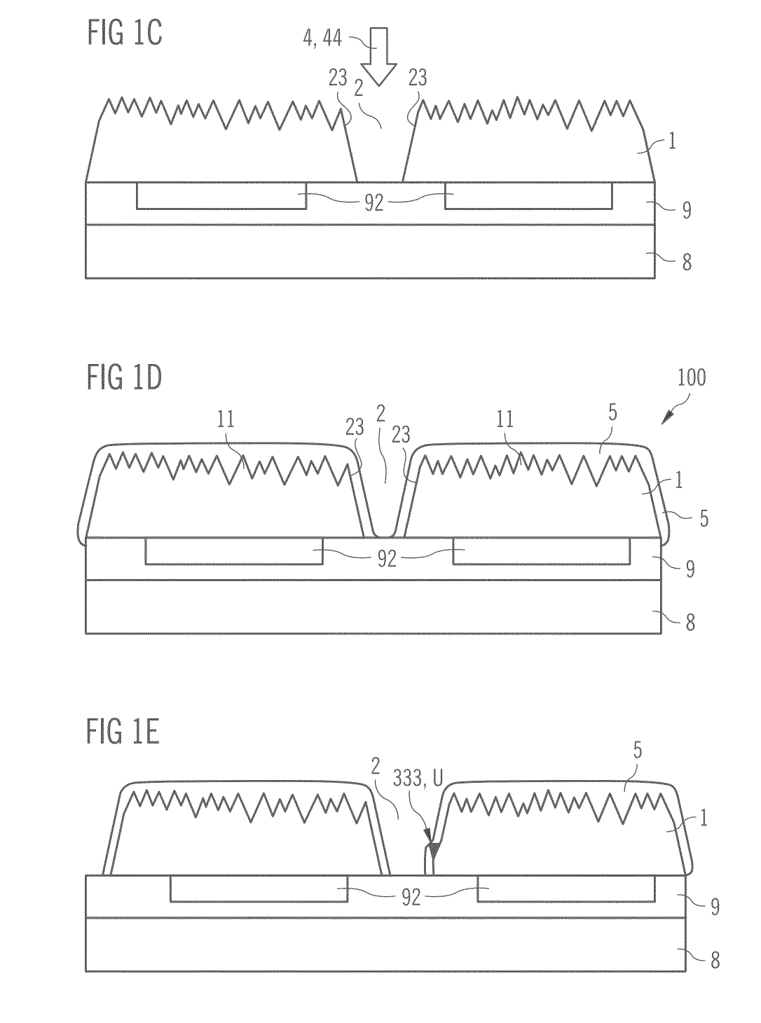

Firstly, FIG. 1A shows a schematic lateral view of a carrier element 8 which comprises a mounting surface 81 and a support surface 82 opposite the mounting surface 81. The carrier element 8 can be a carrier substrate which is formed with a semiconductor material. A connecting means 9 is applied to the mounting surface 81 of the carrier element 8, wherein minor elements 92 are disposed next to each other in the lateral direction L via a surface 91 of the connecting means 9 facing away from the carrier element 8. The minor elements 92 and also the outer surface 91 of the connecting means 9 have a semiconductor body 1 applied thereto which in this case is formed with an epitaxially grown semiconductor layer sequence. The semiconductor body 1 comprises a surface 11 facing away from the carrier element 8, and at least one active zone 12 suitable for generating radiation and the semiconductor body is formed in this case with indium gallium nitride.

A structuring process 3 is performed on the semiconductor body 1 via the surface 11 in a lateral direction L between the two mirror elements 92.

FIG. 1B shows a schematic lateral view of how a trench 2 is incorporated into the semiconductor body 1 via the surface 11 by means of the structuring process 3, wherein in the region of the trench 2 the semiconductor body 1 is completely removed. The trench 2 completely breaks through the active zone 12 in a vertical direction V and subdivides this zone in the lateral direction L. In the region of the trench 2, the outer surface 91 of the connecting means 9 completely forms a base surface 22 of the trench 2, wherein lateral surfaces 23 of the trench 2 are formed completely by the semiconductor body 1.

It is also apparent that the structuring process 3 produces and leaves behind structuring residues 333 on the lateral surfaces 23. The structuring residues 333 can be residues of the semiconductor material of the semiconductor body 1 and/or organic residues, e.g., a photoresist, used during the structuring process 3.

In particular, in FIG. 1B a wet-chemical cleaning process 45 is already performed on the lateral surfaces 23 as an element of the cleaning process 4. The wet-chemical cleaning process 45 can include an application of a buffered oxidized etchant (BOE) and/or an application of hydrofluoric acid. However, this type of cleaning process merely constitutes rough cleaning of the lateral surfaces 23 and is not able to remove and/or strip the structuring residues 333 from the lateral surfaces 23. In other words, even after the wet-chemical cleaning process 45 has been performed the structuring residues 333 remain on and/or in the region of the lateral surfaces 23.

FIG. 1C shows a schematic lateral view of a next step of the method described in this case, in which a plasma cleaning process 44 is performed at least on the lateral surfaces 23 as an element of the cleaning process 4. Thereby it is evident that the structuring residues 333 are removed by means of the plasma cleaning process 44. In other words, after the plasma cleaning process 44 has been performed on the lateral surfaces 23, these lateral surfaces are substantially free of the structuring residues 333.

FIG. 1D shows a schematic lateral view of a further step of a method described in this case, in which a passivation layer 5 is applied completely to the lateral surfaces 23 and also to the surface 11. In so doing, the passivation layer 5 is also free of the structuring residues 333 and extends without interruption on the lateral surfaces 23 and also on the surface 11. The passivation layer can be formed with at least one of the materials SiO₂, SiN, TiO₂, Al₂O₃ and/or Si.

FIG. 1E shows a schematic lateral view of an optoelectronic semiconductor chip, in which for the production thereof the plasma cleaning process 44 described in this case is omitted. As already mentioned above, after only the wet-chemical cleaning process 45 has been performed, the structuring residues 333 remain on the lateral surfaces 23. If the passivation layer 5 is then applied to the lateral surfaces 23, and thus also to the structuring residues 333, the structuring residues 333 can cause interruptions U in the passivation layer 5 and adhesion problems on the semiconductor body 1. This can result in leakage currents on the lateral surfaces 23 which adversely influence a small current behavior of the optoelectronic semiconductor chip. In particular, the structuring residues 333 and therefore such a flawed application of the passivation layer 5 during the operation of this type of optoelectronic semiconductor chip can result in a fall-off in the operating voltage and thus in a malfunction of the optoelectronic semiconductor chip.

In other words, by performing a plasma cleaning process 44 on the lateral surfaces 23, as explained in conjunction with FIGS. 1A to 1D, a small current behavior is improved and the operating life of the entire optoelectronic semiconductor chip 100 is thus increased in a cost-effective manner.

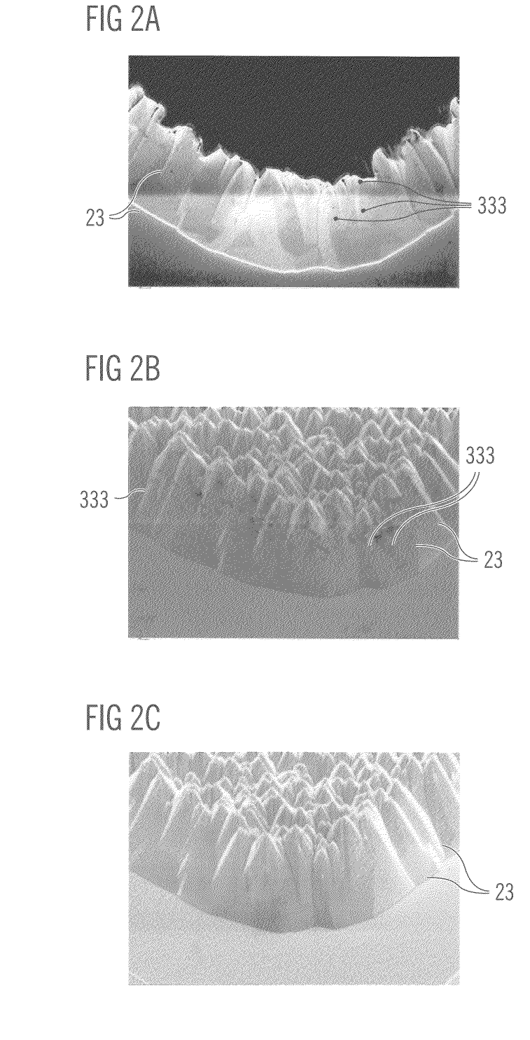

FIG. 2A shows a microscopic lateral image of a section of the lateral surfaces 23 of the trench 2 directly after the structuring process 3 has been performed. It shows structuring residues 333 which remain on and/or in the region of the lateral surfaces 23 and are produced by the structuring process 3.

FIG. 2B shows a further microscopic lateral image, at the same location as FIG. 2A in the semiconductor body 1, directly after the wet-chemical cleaning process 45 thereof has been performed, wherein it is evident that even after the wet-chemical process 45 has been performed the structuring residues 333 still remain in the semiconductor body 1 and/or on the lateral surfaces 23 of the semiconductor body 1.

FIG. 2C shows a microscopic lateral image of the same section as FIGS. 2A and 2B. It is shown that after the plasma cleaning process 44, described in this case, has been performed on the lateral surfaces 23 of the semiconductor body 1, the semiconductor body 1 and/or lateral surfaces 23 of the semiconductor body 1 are free of the structuring residues 333. In other words, the implementation of the plasma cleaning process 44 initially leads to the reduction in the number and/or spatial expansion of the structuring residues 333. Conversely, this means that the wet-chemical cleaning process 45 does not lead to a reduction in the number and/or a spatial expansion of the structuring residues 333, particularly not in comparison with the plasma cleaning process 45 described in this case.

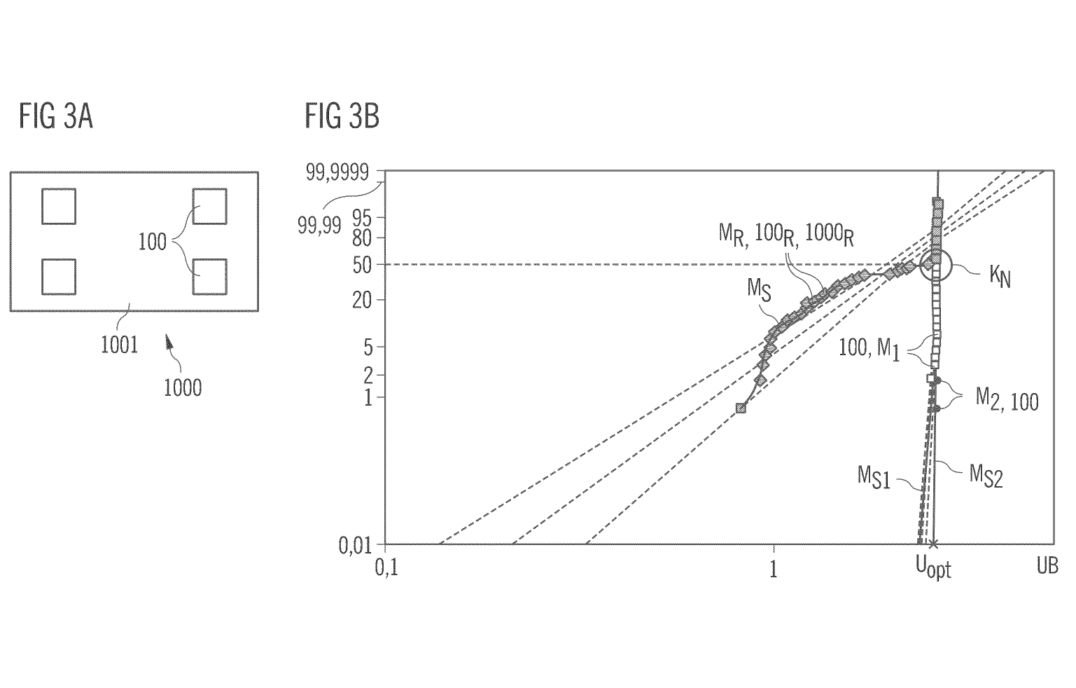

FIG. 3A shows a schematic plan view of an optoelectronic semiconductor device 1000, described in this case, in which a plurality of optoelectronic semiconductor chips 100, which are described in this case and are arranged in the manner of a matrix, are disposed on a carrier 1001 of the semiconductor device 1000. The optoelectronic semiconductor chips 100 described in this case can be electrically conductively contacted to each other in a presettable manner, e.g., via strip conductors located in or on the carrier 1001.

FIG. 3B shows a graph plotting individual voltage measurement values of individual optoelectronic semiconductor chips 100 described, inter alia, in this case.

Firstly, 100 voltage reference measurement values M_{R} of 100 individual reference semiconductor chips 100R of a reference semiconductor device 1000R are plotted. Each of the voltage reference measurement values M_{R} is unequivocally allocated in each case a reference semiconductor chip 100R. With the exception of the plasma cleaning process 44, the reference semiconductor chips 100R are produced by means of the method described in this case. In other words, the reference semiconductor chips 100R of the reference semiconductor device 1000R have the structural residues 333 on their lateral flanks. The respective voltage U_{B}, at which the individual reference semiconductor chips 100R are still operated after 1000 total operating hours, at an operating current of 100 μA, has been measured.

The voltage measurement values M₁ and M₂ are each allocated to an optoelectronic semiconductor chip 100, described in this case, of an optoelectronic semiconductor device 1000 described in this case. In this case, the individual voltage measurement values M₁ and M₂ are measured after 1000 total operating hours at the operating current of 100 μA.

The 100 optoelectronic semiconductor chips 100 which are allocated to the 100 voltage measurement values M₁ are produced using only the plasma cleaning process 44 described in this case. The wet-chemical cleaning process 45 is therefore omitted for the production of these semiconductor chips 100.

In contrast thereto, the 100 voltage measurement values M₂ are each allocated those 100 optoelectronic semiconductor chips 100 which are described in this case and which are produced in addition by means of the wet-chemical cleaning process 45.

In relation to the reference semiconductor device 1000R, it is evident that after the measuring time of 1000 total operating hours, approximately 50% of the individual semiconductor chips 100R can still be operated or are operated at an ideal operating voltage U_{OPT}. Below the 50% threshold, a measurement curve M_{S} established by the measurement points M_{R} is bent in the direction towards lower operating voltages U_{B}. This type of bend is associated with a fall-off in this operating voltage U_{B}.

It is also evident that as a result of this type of fall-off in the operating voltage U_{B} after the 1000 operating hours already 5% of the semiconductor chips 100R of the semiconductor device 1000R are operated at an operating voltage U_{B} of less than one volt. If a location K_{N} on the bend of the measurement curve M_{S} within the plot of the graph is taken as the location from which the respective semiconductor chip 100R malfunctions, after 1000 operating hours of the reference device 1000R only about 50% of the semiconductor chips 100R can be rendered usable for applications.

It is also evident in the plotted graph of FIG. 3B that neither a measurement curve Mₛ₁ of the measurement values M₁ nor a measurement curve Mₛ₂ of the measurement values M₂ has this type of bend. Moreover it is evident that all of the measurement values of the individual semiconductor chips 100 remain, within an operating tolerance, in the region of the U_{OPT} and also remain available for applications even after 1000 hours of total operation time. In other words, the optoelectronic semiconductor chips 100 described in this case have a significantly increased operating life and do not experience any fall-off in the operating voltage U_{B}.

The invention described in this case is not restricted by the description with reference to the exemplified embodiments. On the contrary, the invention includes each new feature and each combination of features, including in particular each combination of features in the claims. This also applies when this feature or this combination itself is not stated explicitly in the claims or the exemplified embodiments.

1-12. (canceled)

13. A method of producing a plurality of optoelectronic semiconductor chips, the method comprising:
providing a semiconductor body that comprises a surface and an active zone suitable for generating radiation;
incorporating a trench into the semiconductor body using a structuring process performed over the surface of the semiconductor body, wherein parts of the semiconductor body are removed in a region of the trench, and wherein the trench breaks through the active zone in a vertical direction;
performing a cleaning process on exposed locations of the semiconductor body in the region of the trench, wherein the cleaning process includes a plasma cleaning process that reduces a number and/or a spatial expansion of structuring residues at exposed locations of the semiconductor body at least in the region of the trench; and
applying a passivation layer to exposed locations of the semiconductor body in the region of the trench.

14. The method as claimed in claim 13, wherein, after the plasma cleaning process has been performed, exposed locations of the semiconductor body at least in the region of the trench are substantially free of the structuring residues.

15. The method as claimed in claim 13, wherein the plasma cleaning process comprises application of Ar, Cl, F, N₂, N₂O and/or O₂ to the exposed locations of the semiconductor body in the region of the trench.

16. The method as claimed in claim 13, wherein the semiconductor body is based upon a III-nitride semiconductor material.

17. The method as claimed in claim 13, wherein the cleaning process includes a wet-chemical cleaning process.

18. The method as claimed in claim 17, wherein the wet-chemical cleaning process includes application of a buffered, oxidized etchant and/or application of hydrofluoric acid to the exposed locations of the semiconductor body in the region of the trench.

19. The method as claimed in claim 17, wherein firstly the wet-chemical cleaning process is performed on the exposed locations of the semiconductor body in the region of the trench and subsequently the plasma cleaning process is performed on these locations.

20. The method as claimed in claim 13, wherein the passivation layer is formed with or contains one or more of the materials selected from the group consisting of SiO₂, SiN, TiO₂, Al₂O₃ and Si.

21. The method as claimed in claim 13, wherein the semiconductor body is separated into individual optoelectronic semiconductor chips in the region of the trench.

22. An optoelectronic semiconductor chip, comprising:
a semiconductor body that comprises a surface and an active zone suitable for generating radiation; and
a passivation layer applied to exposed locations of the semiconductor body in a region of lateral flanks of the semiconductor body;
wherein the semiconductor body, at least on the lateral flanks, is substantially free of structuring residues; and
wherein the passivation layer extends without interruption on the applied locations.

23. An optoelectronic semiconductor device, having a plurality of optoelectronic semiconductor chips as claimed in claim 22.

24. A semiconductor chip, which is produced by the method as claimed in claim 13.

25. The semiconductor chip according to claim 24, wherein the semiconductor chip comprises:
a semiconductor body that comprises a surface and an active zone suitable for generating radiation; and
a passivation layer applied to exposed locations of the semiconductor body in a region of lateral flanks of the semiconductor body;
wherein the semiconductor body, at least on the lateral flanks, is substantially free of structuring residues; and
wherein the passivation layer extends without interruption on the applied locations.
